(19) United States
(12) Patent Application Publication
(10) Pub. No.: US 2018/0340991 A1
(43) Pub. Date: Nov. 29, 2018

(54) HIGH Q-FACTOR MAGNETIC RESONANCE IMAGING RADIO FREQUENCY COIL DEVICE AND METHODS

(71) Applicant: THE MEDICAL COLLEGE OF WISCONSIN, INC., MLWAUKEE, WI (US)

(72) Inventors: Richard Raymond Mett, Cedarburg, WI (US); James Stuart Hyde, Dousman, WI (US); Jason Walter Sidabras, Milwaukee, WI (US)

(21) Appl. No.: 15/528,447

(22) PCT Filed: Nov. 20, 2015
(86) PCT No.: PCT/US2015/061882

§ 371 Date: May 19, 2017

Related U.S. Application Data
(60) Provisional application No. 62/082,493, filed on Nov. 20, 2014.

(51) Int. Cl. G01R 33/341; G01R 33/34

(52) U.S. Cl. CPC G01R 33/341; G01R 33/3628; G01R 33/34053; G01R 33/34092

(57) ABSTRACT

High Q-value radio frequency (RF] coils are described. In general, the RF coils include multiple conductor layers that at least partially overlap to define a capacitive region that equalizes current flowing in each conductor. In some instances, the RF coil includes sets of layered conductors, where each set of layered conductors overlaps in an overlap region. In some other instances, the RF coil includes a spiraled conductor coupled to a dielectric material, where the number of turns of the spiral defines the overlap area. Multiple spiraled conductors can be interleaved. An equalization coil can also be provided to equalize currents along an axial dimension of each conductor in such RF coils. The thickness of the conductors is less than three skin depths, and preferably less than one skin depth, to overcome skin-depth limitations.

### CROSS-REFERENCE TO RELATED APPLICATIONS

This application claims the benefit of U.S. Provisional Patent Application Ser. No. 62/082,492, filed on Nov. 20, 2014, and entitled “HIGH Q-FACTOR RF COIL DEVICE AND METHODS.”

### STATEMENT REGARDING FEDERALLY SPONSORED RESEARCH

This invention was made with government support under EB001980 and EB00215 awarded by the National Institutes of Health. The government has certain rights in the invention.

### BACKGROUND OF THE INVENTION

The subject matter disclosed within generally relates to radio frequency (RF) coils, and specifically surface coils for use in Magnetic Resonance Imaging (MRI) systems. MRI systems rely on both magnetic field and RF energy to create images. Generally, as the magnetic field strength increases, the optimum RF frequency increases proportionally. For example, the optimum RF frequency for a magnetic field strength of one Tesla (T) can be about 43 MHz. However, an optimum RF frequency for a magnetic strength of 3 T can be about 128 MHz.

MRI systems generally require coils that can act as antennas to transmit and receive RF pulses. Clinical MRI systems generally rely on two types of coil designs. First, MRI systems can use volume coils, which can provide a homogenous RF excitation across a large volume. Volume coils are useful for MRI systems for imaging the whole body, head or extremities. Alternatively, MRI systems can use surface coils. Surface coils generally include single or multi-turn loops of conductive material placed directly over the area to be imaged, and allow higher RF sensitivity than volume coils. The higher RF sensitivity allows for greater imaging resolution than that achieved using volume coils; however, the field of view using surface coils is much smaller than that achieved using volume coils.

In order to further increase the image resolution of surface coil MRI, higher magnetic field strength MRI magnets can be used (3T and 7T). However, with this increased magnetic field strength, high RF frequencies are required. This higher RF frequency requirement can result in increased skin effect resistance. Skin effect is a phenomenon caused by the current flowing through a conductor not flowing uniformly across the cross sectional area of the conductor. Rather, the current flow tends to be concentrated near the surface of the conductor. The depth to which the current actually flows in a conductor is known as “skin depth.” Skin depth decreases (i.e. moves closer to the surface of the conductor) as frequency increases. Low skin depth reduces the cross-sectional area through which current can flow, leading to an increase in resistance. This increase in resistance can negatively impact the performance of a surface coil, as well as induce unwanted heating due to the increased ohmic resistance.

Skin effect can impact the performance of a surface coil by reducing the Q-value (Q) of the surface coil. Q-value is a quantitative measurement of a coil's performance, and is a function of inductance, L, and resistance, R, of the coil. Mathematically, Q-value can be expressed by the equation:

$$Q = \frac{2 π fL}{R} ,$$

where f is the resonance frequency. Thus, it can be seen that as resistance increases, there is a decrease in Q-value. As skin depths can be extremely shallow at the RF frequencies required for high field strength MRI magnets, the Q-value can be significantly impacted. For example, the skin depth for a copper surface coil wire at 300 MHz, the optimum RF frequency for a 7T magnet, is only 3.8 micrometers.

Another disadvantage of present surface coil MRI systems is their limited field of view. In an effort to expand the field of view that can effectively be imaged by surface coils, systems have been developed which rely on arrays of multiple surface coils in various configurations that expand the available field of view while retaining the benefit of the high RF sensitivity when using surface coils. However, these array based surface coil MRI systems have their disadvantages, as placing surface coils in proximity to each other can result in an adverse “proximity effect.” Proximity effect occurs when adjacent conductors are carrying a current, and the magnetic field produced by one or more of the adjacent conductors affects the current distribution in another adjacent conductor. For example, in parallel wires carrying currents in the same direction, the proximity of the currents to each other will cause the currents to concentrate on the most distant surfaces of the wire conductor, thus constraining current flow and thereby increasing resistance beyond what would be predicted based simply on the skin effect. This can have the result of degrading the Q-value more, in addition to the previously discussed skin effect. Additionally, proximity effect is similar to skin effect in that it intensifies as magnetic field strengths increase.

Thus, it would be advantageous to have a method and apparatus that allows for surface coils having high Q-values, which are less susceptible to the skin and proximity effects that plague current coil technologies. This is particularly important as the next generation of clinical MRI scanners requiring ultra-high magnetic fields (7T) begin coming into development.

### SUMMARY OF THE INVENTION

It is an aspect of the present invention to provide a radio frequency coil that includes a first set of layered conductors and a second set of layered conductors.

Each conductor in the first set of layered conductors has a thickness less than three skin depths for a desired resonance frequency, and each conductor in the second set of layered conductors has a thickness less than three skin depths for a desired resonance frequency. The radio frequency coil also includes at least one overlap region where the first set of layered conductors and the second set of layered conductors overlap, thereby defining an overlap surface area. The radio frequency coil also includes a plurality of dielectric layers. Each dielectric layer is disposed between a conductor in the first set of layered conductors and a conductor in the second set of layered conductors, such that each conductor in the first set of layered conductors is spaced apart from each conductor in the second set of layered conductors in the overlap region by a separation distance. The overlap surface area and the separation distance define, in part, a capacitance of the radio frequency coil.

It is another aspect of the present invention to provide a self-resonant radio frequency coil including a conductor and a dielectric material. The conductor has a thickness less than three skin depths for a desired resonance frequency, and is spiraled about a central axis for a number of turns to form a coil with an inner radius and an outer radius that define, in part, an inductance of the radio frequency coil. The coil can have a generally round shape, or can have a square, rectangular, or other shape. The dielectric material is coupled on one side of the conductor. The number of turns, the inner radius, and the conductor thickness are selected to define, in part, a capacitance of the radio frequency coil, and the inductance and capacitance of the radio frequency coil are selected to define the desired resonance frequency.

It is still another aspect of the present invention to provide a pancake radio frequency coil that includes a plurality of interleaved dielectric/conductor sheets. Each dielectric/conductor sheet is spiraled about a common central axis for a number of turns to form a coil of interleaved spirals with an inner radius and an outer radius that define, in part, an inductance of the radio frequency coil. In addition, each dielectric/conductor sheet includes a conductor having a thickness less than three skin depths for a desired resonance frequency, and a dielectric material coupled on one side of the conductor. The number of turns, the inner radius, and the conductor thickness are selected to define, in part, a capacitance of the radio frequency coil. The inductance and capacitance of the radio frequency coil are selected to define the desired resonance frequency.

It is still another aspect of the present invention to provide a high Q-value coil that includes a conductive assembly having at least two overlapping conductive elements that define an overlap area therebetween, and a dielectric material coupled to the conductive assembly. The dielectric material also provides a separation distance between the at least two conductive elements in the overlap area. A thickness of a conductor in the conductive assembly is selected to minimize countercurrents flowing in the conductive assembly.

The foregoing and other aspects and advantages of the invention will appear from the following description. In the description, reference is made to the accompanying drawings that form a part hereof, and in which there is shown by way of illustration a preferred embodiment of the invention. Such embodiment does not necessarily represent the full scope of the invention, however, and reference is made therefore to the claims and herein for interpreting the scope of the invention.

### BRIEF DESCRIPTION OF THE DRAWINGS

FIG. 1A is a sectional view of an example of a meta-metallic coil structure composed of sets of partially overlapping conductive layers.

FIG. 1B is a view of overlapping conductors, which may form a part of a meta-metallic coil structure.

FIG. 1C is a section view of another example of a meta-metallic coil structure composed of two sets of partially overlapping conductive layers.

FIG. 1D illustrates a coil structure wrapped around a cylindrical volume and extending along an axial length.

FIG. 2A is a 3D view of an example of a meta-metallic coil structure constructed from a single conductor/dielectric sheet in a spiral coiled form.

FIG. 2B illustrates an example of a conductor/dielectric sheet that may be used to construct a meta-metallic coil structure.

FIG. 3 is a 3D view of an example of a meta-metallic coil structure constructed as a high-Q value pancake coil arrangement.

FIG. 4 is a sectional view of an example of a meta-metallic coil structure constructed as a tube coil.

FIG. 5A is a side view of an example of a meta-metallic coil structure constructed as a toroidal coil.

FIG. 5B is a top view of the example meta-metallic coil structure constructed as a toroidal coil.

FIG. 5C is a cut-away section of the example meta-metallic coil structure constructed as a toroidal coil.

FIG. 5D is a poloidal cross section of the example meta-metallic coil structure constructed as a toroidal coil.

FIG. 6A is an example of a meta-metallic structure constructed as a set of partially overlapping conductive layers extending along an axial direction.

FIG. 6B is an example of a meta-metallic structure constructed as an axial coil bounded on each end by a dielectric cap.

FIG. 6C is an example of a meta-metallic structure constructed as an axial coil bounded on one end by a dielectric cap.

FIG. 7A is an example of a meta-metallic structure constructed as an axial coil surrounded by a coaxial steering, or equalization, coil.

FIG. 7B is an example of a top view of the meta-metallic structure constructed as an axial coil surrounded by a coaxial steering, or equalization, coil.

FIG. 8 is a plot illustrating Q-value as a function of conductor layer thickness in various different configurations of a meta-metallic structure.

FIG. 9 is an example of a meta-metallic structure constructed as a length of coaxial cable.

### DETAILED DESCRIPTION OF THE INVENTION

The present invention is now described with reference to the drawings, wherein like reference numerals are used to refer to like elements throughout. In the following description, for purposes of explanation, numerous specific details are set forth in order to provide a thorough understanding of the present invention. It may be evident, however, that the present invention may be practiced without these specific details. In other instances, well-known structures and devices are shown in block diagram form in order to facilitate describing the present invention.

Described here are systems and methods for decreasing Ohmic losses and increasing Q-value in metallic coils and resonators at high frequencies. The coils and other conductive structures described here overcome the skin-depth limitation of RF current flow cross section by using layers of conductive foil of thickness less than a skin depth and capacitive gaps between layers. The capacitive gaps can substantially equalize the RF current flowing in each conductive layer, thereby resulting in a total cross sectional dimension for RF current flow that is many times larger than a skin depth. As will be described below in more detail, conductive structures can be constructed based on a minimum layer number for a given total conductor thickness that results in Q-value enhancement over a single thick conductor. This relationship can also be expressed as a maximum conductor layer thickness for a given number of layers. The relationship is due to counter-currents in each foil layer caused by the surrounding RF magnetic fields. Structures that exhibit this effect can be referred to as “meta-metallic.”

While the below disclosure is primarily directed to MRI type systems, it should be known that the below described technology is not limited to use in MRI or other medical imaging technologies. For instance, the meta-metallic structures described here can similarly be constructed for use in nuclear magnetic resonance (“NMR”) and electron paramagnetic resonance (“EPR”) by designing the structures to have inductance and capacitance that provides a resonance frequency suitable for use in NMR or EPR applications.

In MRI, signal-to-noise ratio (“SNR”) is proportional to the coil or resonator quality factor (i.e., Q-value), which can be defined as 2π multiplied by the ratio of electromagnetic energy stored to electromagnetic energy dissipated per cycle. The signal also depends on sample volume compared to the volume over which the RF magnetic field extends (filling factor), RF power, dissipation caused by the sample and spin saturation. However, for a given volume, higher signal can be achieved in coils and resonators with higher Q-values. It is therefore advantageous to maximize Q-value for a given coil or resonator design. In addition, for maximum SNR, RF dissipation in the sample should typically be comparable to the dissipation in the coil or resonator. This can result in an optimum Q-value outside of the range that is possible for typical structures.

As the size of coils and resonators is reduced, the Q-value tends to decrease. This is due to the scaling of the inductance L, which is proportional to loop area, and resistance R, which is proportional to loop circumference,

$$Q = \frac{ω L}{R} ; \qquad ( 1 )$$

where ω is the radian frequency. For metallic structures, the resistance can be expressed as,

$$R ≃ \frac{2 π {r}_{i}}{δ l T} ; \qquad ( 2 )$$

where rᵢ is the inner radius of the structure, l is the axial length of the structure, σ is the conductivity, and T is the current flow thickness. RF fields and currents tend to reside on the surfaces of metallic conductors with a characteristic exponential decay length with depth that is the skin depth,

$$δ = \frac{1}{\sqrt{π f {μ}_{0} σ}} ; \qquad ( 3 )$$

where μ₀ is the magnetic permeability of free space and f is the RF frequency. For frequencies above several MHz, conductor thicknesses are typically large compared to the skin depth. However, it is a discovery of the present invention that multiple layers of thin conductors can be arranged to support RF currents substantially equal to those in a single thick conductor,

T=Nt>δ (4);

where N is the number of thin conductive layers. This effect can thus be achieved by constructing the thin conductors to be thin relative to the skin depth.

If the conductive layers together have an inductance similar to that of the single thick conductor, the Q-value of the layered conductor structure, Q_{f}, is enhanced compared to the thick, solid structure, Qₛ, by the factor T/δ,

$$\frac{{Q}_{f}}{{Q}_{s}} ≃ \frac{T}{δ} . \qquad ( 5 )$$

At 400 MHz, δ=3.3 μm for copper. Consequently, at high frequencies, many thin conductive layers can be used to significantly enhance the Q-value of a typical coil or resonator.

Previous attempts to solve the problems associated with skin and proximity effects have suffered from an inability to effectively reduce skin effect and proximity effect at the higher frequencies needed to operate higher magnetic field strength MRI coils (3 T to 7 T magnets). For example, Litz wire is a well-known technique used to overcome skin effect limitations. Litz wire is generally constructed with a bundle of fine strand conductors separated by an insulator. The conductors are sized such that the radius of each strand is less than a skin depth for a given frequency, causing the RF currents to penetrate the Litz wire as a whole. This can ultimately result in a Litz wire based conductor having a cross sectional area for current flow which can be larger than a solid conductor of similar dimension.

While Litz wire can be used to reduce skin and proximity effect in limited circumstances, they are ineffective for use in coil wiring, and specifically medical imaging coil wiring, as Litz wire is only typically effective at operating frequencies of less than 2 MHz. This is substantially lower than the 128 to 300 MHz needed to operate MRI coils having 3T and 7T magnets. The limitation of Litz wires can be attributed to two major factors: strand size and uneven current flow. Strand size is a considerable factor due to the inverse proportional relationship between skin depth and frequency. Thus, the higher the frequency, the smaller the skin depth resulting in smaller and smaller diameter's for the individual strands in the Litz wire, to the point of impracticality. Uneven current flow is the result of uneven RF currents in the bundle of Litz wire due to proximity effect. The proximity effect associated with Litz wires results in current tending to flow on the outside surfaces of a Litz wire bundle as the size of the Litz wire bundle increases. This localization of the RF currents limits the maximum Q-value by decreasing the cross-section available for RF current flow.

As Litz wires and other known methods of overcoming skin and proximity effects are not effective at higher frequencies, the present technology was designed to incorporate metamaterials. Metamaterials are artificial materials engineered to have properties that may not be found in nature. Specifically, metamaterials can be assemblies of multiple, individual elements fashioned from known microscopic materials such as metals or plastic arranged in repeating patterns. Metamaterials can achieve their desired properties from the design of their structures, rather than just from the materials from which they are composed. Shape, geometry, size, orientation and arrangement of components in metamaterials can all affect electromagnetic radiation in ways that are not readily achieved using more conventional materials.

The coil designs discussed in detail below are designed to take advantage of metamaterial structures that can be predicted to permit relatively uniform current flow in many layers of thin conductors, such as conductive foil, each with a thickness that is preferably less than about one skin depth. For instance, Eqn. (13) below indicates that for a meta-metallic structure constructed with two conductive layers, the optimal thickness of each conductive layer should be less than about 1.2 skin depths. In some embodiments, however, it may be advantageous for the thickness of the conducive layers to not exceed two or three skin depths for a desired frequency. These conductive layers can overlap to effectively form distributed capacitors, separated by an insulating dielectric material. The insulating dielectric material can be nonconducting material with minimal RF loss as commonly used in the field of radio frequency engineering. Non-limiting examples of dielectric materials that can be used include polytetrafluoroethylene (“PTFE”), polyethylene, polypropylene, polystyrene, paraffin wax, silicon dioxide, glass, sapphire, high resistivity silicon, as well as materials such as Rogers RT/Duroid® 5880 or other nonconducting materials with minimal RF losses. Alternatively, materials with large dielectric constants can also be used.

For a single, thick conductor, the power dissipation per unit surface area of the conductor, P_{A}, can be expressed as,

$${P}_{A} = \frac{{H}_{max}^{2}}{σδ} ; \qquad ( 6 )$$

where Hₘₐₓ is an RF magnetic field strength at the conductor surface. The magnetic field strength is equal to the RF current per unit axial length in the conductor (i.e., Hₘₐₓ=I). For a conductive structure composed of a number, N, of thin conductive layers with substantially equal currents in each layer, when the conductor thickness is less than a skin depth, t<δ, the current density in the conductor can be approximated by,

$${J}_{z} = \frac{1}{t} ( {H}_{b} - {H}_{a} ) + \frac{{τ}^{2}}{2 t} ( {H}_{b} ( {x}^{2} - \frac{1}{3} {t}^{2} ) - {H}_{a} ( {( t - x )}^{2} - \frac{1}{3} {t}^{2} ) ) + … ; \qquad ( 7 )$$

where H_{b} is the RF magnetic field H_{y} (x=0); Hₐ is the RF magnetic field H_{y} (x=t); and τ is a complex parameter that can be written in terms of skin depth as,

$$τ = \frac{1 + j}{δ} ; \qquad ( 8 )$$

where j=\sqrt{−1}. The first term in Eqn. (7) represents a constant current throughout the conductor. It is a low-frequency term that persists in the steady-state or direct current limit. The second term in Eqn. (7) is caused by counter-currents (i.e., eddy currents). It can be seen that for the second order term, the current density reverses direction on each side of the conductor. At x=0, the second term is,

$$- \frac{1}{6} {τ}^{2} t ( 2 {H}_{a} + {H}_{b} ) ; \qquad ( 9 )$$

and at x=t the second term is,

$$\frac{1}{6} {τ}^{2} t ( {H}_{a} + 2 {H}_{b} ) . \qquad ( 10 )$$

The strength of these counter-currents is proportional to the magnetic field magnitude on the surface of the conductor. The counter-current strength is also proportional to the conductor thickness. Consequently, the conter-currents can be reduced compared to the low-frequency term by reducing the conductor thickness.

Based on the current density approximation above, the power dissipation per unit area in the thin conductor can be expressed as,

$${P}_{A} = \frac{{H}_{max}^{2}}{σ T} ( 1 + {( \frac{{T}^{2}}{3 N {δ}^{2}} )}^{2} ( 1 - \frac{1}{5 {N}^{2}} ) + … ) ; \qquad ( 11 )$$

where T=Nt and where Hₘₐₓ is the RF magnetic field on one side of the conductor layer set. The sum of the currents per unit axial length in all the conductor layers is equal to I=Hₘₐₓ.

In comparing the first term of Eqn. (11) to the thick conductor limit in Eqn. (6), it is seen that, to the first order, multiple conductive layers have reduced power dissipation by the factor δ/T, compared to a single thick conductor. However, the second term in Eqn. (11) provides the condition for this to be true. In order for the series to converge, the second order term must be smaller than the first. This puts a minimum constraint on the number of layers,

$$N > \frac{1}{3} {( \frac{T}{δ} )}^{2} . \qquad ( 12 )$$

This constraint can be interpreted as the minimum number of layers for a given total conductor thickness, T. From Eqn. (4), this constraint can also be expressed in terms of the maximum layer thickness for a given number of layers,

$$t < \frac{δ}{\sqrt{N \text{/} 3}} . \qquad ( 13 )$$

The Q-value will therefore exhibit a maximum as the number of layers approaches 3(δ/t)². This is because the first-order and second-order dissipation terms scale differently with conductor layer thickness, t. Consequently, there is an optimal number of layers that produces a maximum Q-value for a given conductor layer thickness, t. Similarly, at a fixed number of layers, increasing the layer thickness, t, also produces a maximum Q-value near tₘₐₓ. In both cases, the maximum gain in Q-value occurs when the second-order counter-current dissipation is balanced with the first-order direct current dissipation. Table 1 contains some practical cases for copper at different frequencies.

TABLE 1
Q-value Enhancement Constraints for Copper Layers

| | | |
|---|---|---|
| T | 400 MHz | 9.5 GHz |

| δ | Nₘᵢₙ | δ(μm) | tₘₐₓ (μm) | δ(μm) | tₘₐₓ (μm) |
|---|---|---|---|---|---|
| 5.5 | 10 | 3.3 | 1.8 | 0.68 | 0.37 |
| 7.8 | 20 | | 1.3 | | 0.26 |
| 10 | 33 | | 0.99 | | 0.20 |
| 20 | 130 | | 0.50 | | 0.10 |
| 100 | 3300 | | 0.099 | | 0.020 |

From these results, the Q-value enhancement factor for the meta-metallic structures described here can be understood as follows. If the conductive layer thickness is significantly less than the maximum given by Eqn. (13), the Q-value enhancement factor is accurately given by T/δ because the counter-current dissipation is small compared to the first-order dissipation. However, if the conductor layer thickness is near the maximum, the Q-value enhancement factor is about one-half of T/δ because the first-order and second-order dissipation are nearly equal, doubling the total Ohmic dissipation.

By differentiating Eqn. (11) with respect to t and setting the result equal to zero, a theoretical conductor layer thickness for minimum Ohmic dissipation can be obtained as,

$${t}_{opt} = \frac{{3}^{1 \text{/} 4} δ}{\sqrt{N}} . \qquad ( 14 )$$

This conductor layer thickness, tₒₚₜ, is about 32 percent thinner than the maximum thickness, tₘₐₓ, from Eqn. (13). Thus, meta-metallic structures as described herein preferably have conductor layers with a thickness between tₒₚₜ and tₘₐₓ.

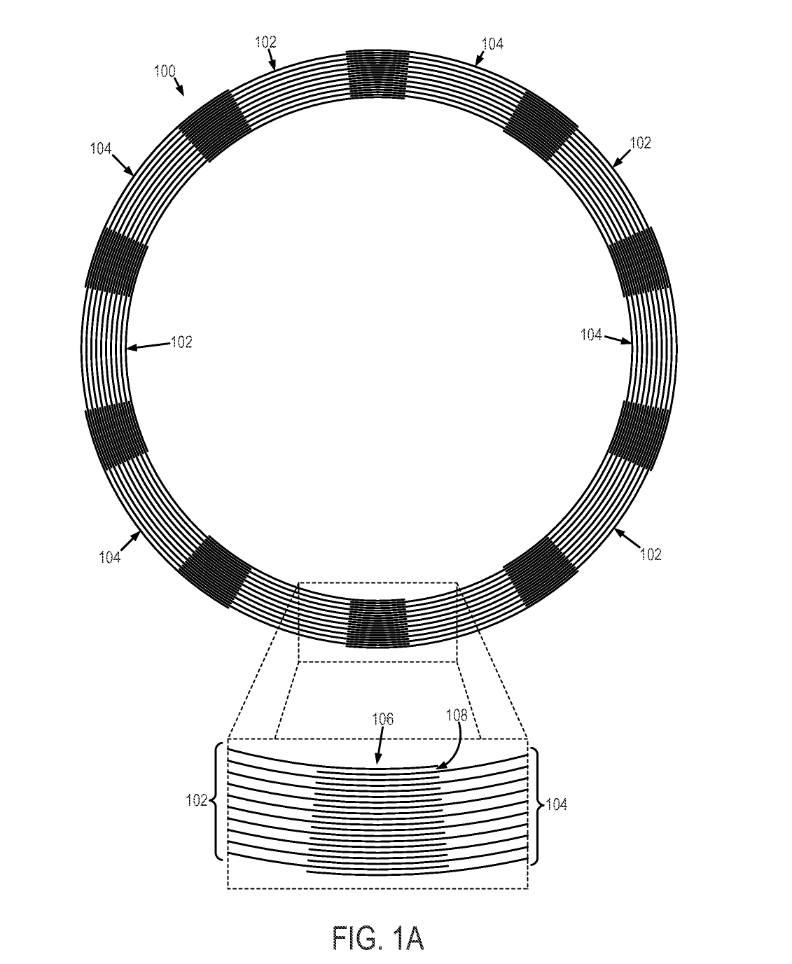

Turning now to FIG. 1A, an example of a coil structure 100 constructed from an overlapping conductive layer conductor is illustrated. The coil structure 100 is made up of layered sets of conductors that overlap in overlapping regions. As one example, the layered sets of conductors can comprise layers of conductive foil. A first set of layered conductors 102 can carry a current. The first set of layered conductors 102 can then overlap with a second set of layered conductors 104 in an overlap region area or region 106. Each conductor in the first and second sets of conductors 102, 104 preferably has a thickness less than about three skin depths. In some embodiments, the thickness of each conductor is less than one skin depth. As shown in FIG. 1A, each set of layered conductors can include a plurality of subsets, each containing a plurality of conductors that are arranged in generally parallel layers that are spaced apart. Alternatively, as shown in FIG. 1C, the first and second set of layered conductors can be the only sets of conductors, and can each include a plurality of conductors that are arranged in generally parallel layers that are spaced apart.

In some embodiments, such as the one shown in FIG. 1D, the first set of layered conductors 102 and the second set of layered conductors 104 are wrapped around a cylindrical volume 150 having a central axis 152 and a height, h, that defines an axial length, l, of the coil structure 100. In these embodiments, the coil structure 100 takes a generally tubular form disposed about the radius, r, of the cylindrical volume 150. The conductors in the first and second sets of layered conductors 102, 104 thus extend from one end of the cylindrical volume to the other end of the cylindrical volume.

The first set of layered conductors 102 and the second set of layered conductors 104 can overlap along a predetermined length of the first set of layered conductors 102 and the second set of layered conductors 104. The first set of layered conductors 102 and the second set of layered conductors 104 can be separate conductors. Alternatively, the first set of layered conductors 102 and the second set of layered conductors 104 can be opposite ends of the same conductors. The conductors can all be separated by an insulating layer 108. In one embodiment, the insulating material can be a dielectric material, such as PTFE.

As illustrated in FIG. 1B, adjacent conductors in the coil structure 100 are separated by a distance, d, and the overlap area 106 is associated with a surface area, A, on each conductor. The overlap area 106 can result in a capacitive area where the first and second sets of layered conductors 102, 104 form capacitive gaps between the conductors separated by the insulating layers 108. The overlap of the first set of layered conductors 102 and the second set of layered conductors 104 can thus form a capacitance between adjacent conductors and between the insulating layers 108. Current flowing along the conductors can cause opposite charge to build up on adjacent conductors, and can charge and/or discharge the capacitor formed between adjacent conductors and the insulating material 108. This overlap can cause the RF currents flowing through the first set of layered conductors 102 and the second set of layered conductors 104 to be substantially equal in each of the first and second sets of layered conductors 102, 104.

The distance of the overlap area 106 can be proportional to the desired capacitance. The desired capacitance can be proportional to the current in an individual conductor. This can provide for capacitive balancing of the RF currents in the conductors. If the thickness of each conductor in the sets of layered conductors 102, 104 is less than about two or three skin depths, the balancing of currents can result in the total cross section of current flow to be the sum of the conductor thicknesses, instead of a single skin depth when using a single conductor.

Additionally, as the equivalent resistance of the current path is inversely proportional to the cross sectional area of current flow, the resistance is therefore inversely proportion to the sum of the conductor thicknesses instead of the skin depth. The increase in cross sectional area for current flow, and subsequent reduction in the effective resistance of the conductor can further reduce resistive losses, and thereby can reduce heat produced by current flowing through the conductors. Further, since the sum of the conductor thicknesses, which determines the cross sectional area for current flow, can be much larger than the skin depth for an individual conductor, substantially higher Q-values can be achieved over currently known configurations. The geometry of balanced currents in multiple conductors in the sets of layered conductors 102, 104 increases the cross sectional area for current flow, and is not limited by the skin effect. Furthermore, if the conductor thickness is greater than about three skin depths, the boundary condition J=\hat{n}×H on the conductor surfaces can cause counter-currents in the conductors that can reverse the direction of current on opposite sides of the conductors in the sets of layered conductors 102, 104. These counter-currents can change the circuit geometry and can further decrease the Q-value by several orders of magnitude.

The first set of layered conductors 102 and the second set of layered conductors 104 can generally be very thin relative to the skin depth of the conductive material from which the conductors are composed. In one embodiment the first set of layered conductors 102 and the second set of layered conductors 104 can be made of a metallic foil. Metallic foil conductors can be made of suitable conductive materials. For example, the metallic foil conductors can be constructed using stainless steel, copper, silver, etc. While the conductors can have varying thicknesses, optimum results are obtained where the thickness for each of the plurality of conductors is less than about two or three skin depths. As seen in Eqn. (3), skin depth can be determined as a function of the properties of the conductor material and the desired frequency of the RF current. Alternatively, the metallic foil conductors can be made of a gilding foil. In one example, the gilding foil can have a thickness of about 2 micrometers.

In other embodiments, the first set of layered conductors 102 and the second set of layered conductors 104 can be constructed by depositing a conductive material on the dielectric insulating layers 108. As one example, the conductive material can be deposited by electrodeposition. As another example, the conductive material can be deposited by physical vapor deposition (“PVD”).

Overlapping layered conductors with capacitive gaps can provide uniform flow of current, which can substantially reduce proximity effects. In FIG. 1B, RF current that flows in from the left on conductors 102 can decrease linearly in overlap area 106 to zero at the end of the conductors 102 at the right side of overlap area 106. Simultaneously, the current increases from zero at the left edge of the conductors 104 to the same level of current at the right edge of overlap area 106. The same current enters overlap area 106 as leaves overlap area 106 but on different conductors 102, 104. The conductive layers should be no thicker than three skin depths for the desired resonance frequency of the RF coil, and preferably less than about one skin depth, or there will be countercurrents on opposite sides of the conductors in the sets of layered conductors 102, 104.

The proximity effect can move the RF current to the outer edge of a conductor where RF current can flow along an edge. Multiple methods (in various combinations) can be used to mitigate the proximity effect. For example, the conductor edges parallel to current can be made relatively thicker than the rest of the conductor (e.g., several skin depths compared to less than two or three skin depths). As another example, the thickness of the insulating layer 108 can be increased, thereby increasing the distance between conductors in the sets of layered conductors 102, 104. Also, the conductors can be made wider in a dimension perpendicular to current flow; the number of conductor edges parallel to the current flow can be reduced or minimized; and the number of conductor edges parallel to the current flow can be placed where the RF magnetic field is weak.

Overlapping conductors with capacitive gaps can further be designed into coils such that the resonance frequency can be dependent on the loop inductance and the total gap capacitance,

$$f = \frac{1}{2 π \sqrt{LC}} ; \qquad ( 15 )$$

where C is the total capacitance of the meta-metallic conductive structure 100 and L is the total inductance of the meta-metallic conductive structure 100. In FIG. 1A, first plurality of conductors 102 includes ten foil conductors overlapping ten foil conductors in the second plurality of conductors 104. The capacitance between the first plurality of conductors 102 and the second plurality of conductors 104 is,

$${C}_{b} = \frac{19 {ɛ}_{0} {ɛ}_{r} A}{d} ; \qquad ( 16 )$$

where ε₀ is the electric permittivity of free space; εᵣ is the relative dielectric constant of the dielectric material of the insulating layer 108 between the conductors in the sets of layered conductors 102, 104; A is the area of overlap between one conductor in the first set of layered conductors 102 and an adjacent conductor in the second set of layered conductors 104 (i.e., overlap area 106), as illustrated in FIG. 1B; and d is the spacing between these conductors, as illustrated in FIG. 1B.

For ten overlapping areas 106 in the coil structure 100, the total capacitance C is the series combination of C_{b},

$$C = \frac{{C}_{b}}{10} . \qquad ( 17 )$$

The total inductance of the loop can be estimated from the formula for the inductance of a single turn loop,

$$L = \frac{1}{\frac{1}{{L}_{i}} + \frac{1}{{L}_{o}}} ; \qquad ( 18 )$$

where, neglecting end effects, the inner and outer inductance are given by the following equations:

$$\begin{matrix}{L}_{i} = \frac{{μ}_{0} {π ( {r}_{i} + {r}_{o} )}^{2}}{4 l} ; & ( 19 ) \\ {L}_{o} = \frac{{μ}_{0} π ( {r}_{s}^{2} - {r}_{o}^{2} )}{l} ; & ( 20 )\end{matrix}$$

where rᵢ is the inner radius of the loop, rₒ is the outer radius of the loop, rₛ is the inner radius of the conducting shield, and l is the axial length. Finite element modeling can provide a more precise resonance frequency.

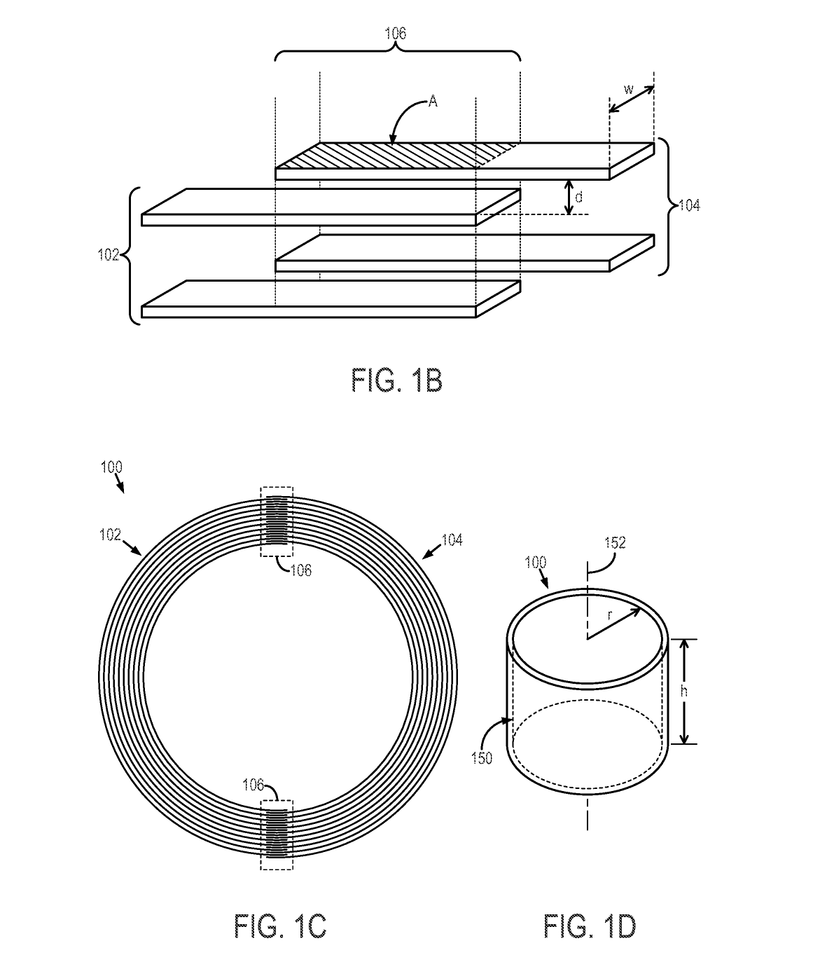

Turning now to FIGS. 2A and 2B, a single conductor/dielectric sheet 202 can be seen formed into a self-resonant coil 200. The conductor/dielectric sheet 202 can be a strip of metallic foil 204 or other suitable conductor coupled to or deposited on a dielectric material 206. This configuration is an extreme example of one set of overlapping conductors forming a single loop with a single gap. By forming the coil 200 as a spiral of a single conductor/dielectric sheet 202 overlapping for many turns, the RF current can be as low as zero on each end of the foil conductor 204 The current builds up to a maximum (similar to the first half cycle of a sine wave) near the physical center of the foil conductor 204. The current in each turn can be in the same azimuthal direction. Although the currents are not equal in each turn, they can be sufficiently similar in adjacent turns near the center of the coil 200 to provide a total cross section for current flow over all the turns in the coil 200 larger than a skin depth. In one embodiment, the metallic foil 204 can be a silver foil. The dielectric material 206 can be a PTFE type dielectric material. The thickness of the metallic foil 204 can be determined based on the type of material and the desired operating frequency. For example, the thickness of the metallic foil 204 can be determined using Eqns. (13) and (14) with N=4:

$$\frac{{3}^{1 \text{/} 4} δ}{2} < t < \frac{{3}^{1 \text{/} 2} δ}{2} ; \qquad ( 21 )$$

where the skin depth, δ, is given by Eqn. (3). Additionally, the resonance frequency can be estimated from Eqn. (15), where the total capacitance is given approximately by,

$$C = \frac{{ɛ}_{0} {ɛ}_{r} ( N - 1 ) π ( 2 {r}_{i} + Np )}{p - t} ; \qquad ( 22 )$$

where ε₀ is the electric permittivity of free space, εᵣ is the relative dielectric constant of the dielectric material between the conductor layers, N is the number of turns, rᵢ is the inner radius of the spiral, p is the pitch of the spiral, and t is the thickness of the conductor. The inductance of the coil can be estimated by Eqns. (18)-(20). Finite element modeling can give a more precise resonance frequency.

The dielectric material 206 can have multiple dimensions based on the required application. In one example the dielectric material 206 can have a width of about 1 cm, a length of about 16 cm (about 4.5 turns), a spacing between metallic foils 204 of about 1.2 mm, an inner radius of 3 mm and a metallic foil 204 thickness of about 2.2 micrometers for a resonance frequency near 400 MHz.

In some other embodiments, the single conductor/dielectric sheet 202 can include a dielectric material that has been electroplated by a conductive material. One example of such an electroplated material is CuFlon (Polyflon Company; Norwalk, Conn.), which is constructed by electroplating PTFE with copper. It will be appreciated that other dielectric materials can be similarly electroplated and, in addition, conductive materials other than copper can be used for the electroplating process.

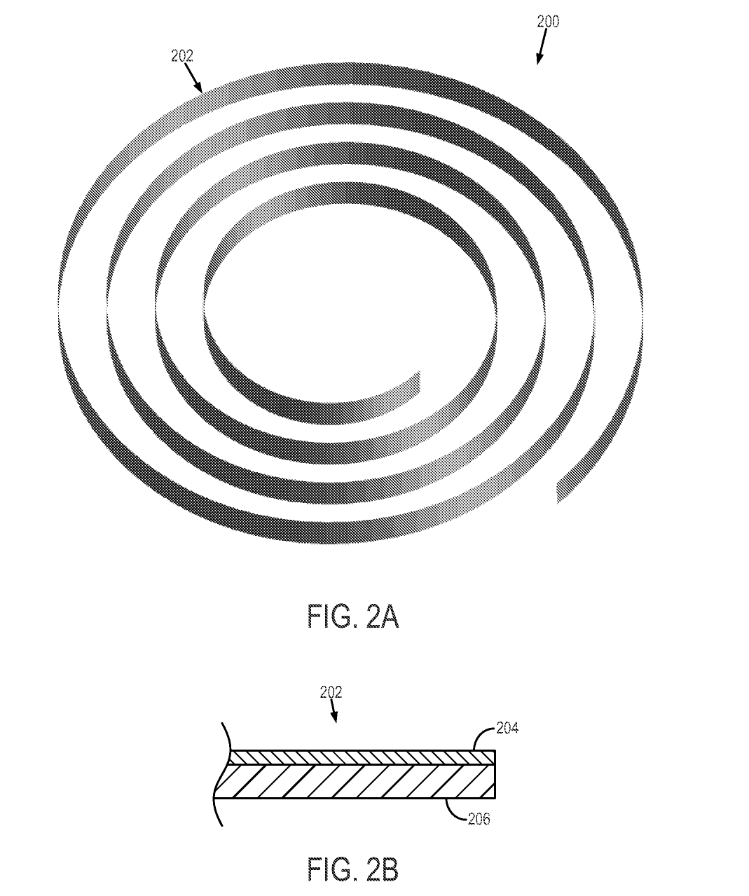

Turning now to FIG. 3, an example of a pancake coil 300 is illustrated. This coil 300 includes four foil spiral coils 200, such as those shown in FIG. 2A, coiled together and separated so that the four coils 200 can be coiled together without physically contacting each other. The spacing between adjacent metallic foil 204 layers can be one-fourth the turn spacing of a single foil, which nearly preserves the resonance frequency compared to FIG. 2A. The pancake coil 300 can be formed from a plurality of single conductor/dielectric sheets 202, such as those shown in FIG. 2B. While different quantities of single conductor/dielectric sheets 202 can be used, the example pancake coil 300 of FIG. 3 used four single conductor/dielectric sheets 202. However, more than four single conductor/dielectric sheets 202 or less than four single conductor/dielectric sheets 202 can also be used. Because the pancake coil 300 is composed of four sets of 3.5 turn spirals, N=4×3.5=14, and the optimum conductor thickness given by Eqns. (13) and (14) is smaller: 1.4 micrometers at 400 MHz.

These individual conductor/dielectric sheets 202 can have the same dimensions and be made of the same material, or alternatively, some or all of the conductor/dielectric sheets 202 can be constructed using different conductive materials, dielectric materials, or both. To form pancake coil 300 the individual conductor/dielectric sheets 202 can be layered by stacking each on top of the other. The stack of conductor/dielectric sheets 202 can then be spiraled around a fixed diameter and inserted into a dielectric holder 302 having a cylindrical cavity with an inner diameter that holds the outer diameter of the coil. For example, the dielectric holder 302 used in FIG. 3 has an outer diameter of 1.6 cm. However, dielectric holders 302 with outer diameters larger and/or smaller than 1.6 cm can also be used. Additionally, in this pancake coil arrangement, the thickness of the dielectric material in the conductor/dielectric sheets 202 can determine the separation distance, d, of the conductors. In one example, the thickness of the dielectric material 206 can be about 50 micrometers. The spacing of the conductors in pancake coil 300 can determine the operating frequency; therefore, the thickness of the dielectric material 206 can be selected based on the desired operating frequency for the intended field strength.

In the pancake coil 300 of FIG. 3, each single conductor/dielectric sheet 202 can carry current independently. Additionally, each single conductor/dielectric sheet 202 can be strongly magnetically coupled to the other single conductor/dielectric sheets 202 in pancake coil 300. This pancake coil construction allows for a significant overlap of the conductors as discussed above. This overlap, resulting in a capacitance between the individual conductor/dielectric sheets 202, can cause the RF currents flowing between the conductor/dielectric sheets 202 to be substantially equal. This can reduce the effect of skin depth, as discussed above. Further, the design of the pancake coil allowing for strong magnetic coupling between the conductor/dielectric sheets 202 can allow for the structure to resonate as an integrated body at a single frequency. Further, the strong magnetic coupling can allow for the pancake coil 300 of FIG. 3 to resonate at a single frequency even if the conductor/dielectric sheets 202 are not exactly identically sized or precisely oriented. In pancake coil 300, the bandwidth at the resonance frequency can be determined by the net losses (Q-value) only.

Coil designs such as the pancake coil 300 can be limited in efficiency, however, due to the potential impact of proximity effect, which can cause current to flow more densely along the axial edges of the coil. As the axial edges of the conductors become thinner, the concentration of current on the axial edges can increase. This can result in lower Q-values in pancake coil 300 as the edges of the foil conductors get thinner.

Proximity effect can cause RF current to distribute non-uniformly in a conductor. Specifically, proximity effect can be caused by eddy currents induced by the RF magnetic field produced by currents in nearby conductors and by the currents in the conductor itself. As an example, the currents in two rounded conductors carrying current in a parallel direction will tend to concentrate on the side of each conductor at a point furthest from the other conductor. This non-uniform current distribution can cause the effective cross section for current flow to decrease and the resistance of the conductors to increase.

Proximity effect can be reduced by both minimizing the number of conductor edges with current flowing along them, and placing the conductor edges with currently flowing along the edge in a region of relatively weak RF magnetic field. Conductor edges that terminate in the end of a capacitor can have zero current flow and, therefore, do not contribute to the proximity effect

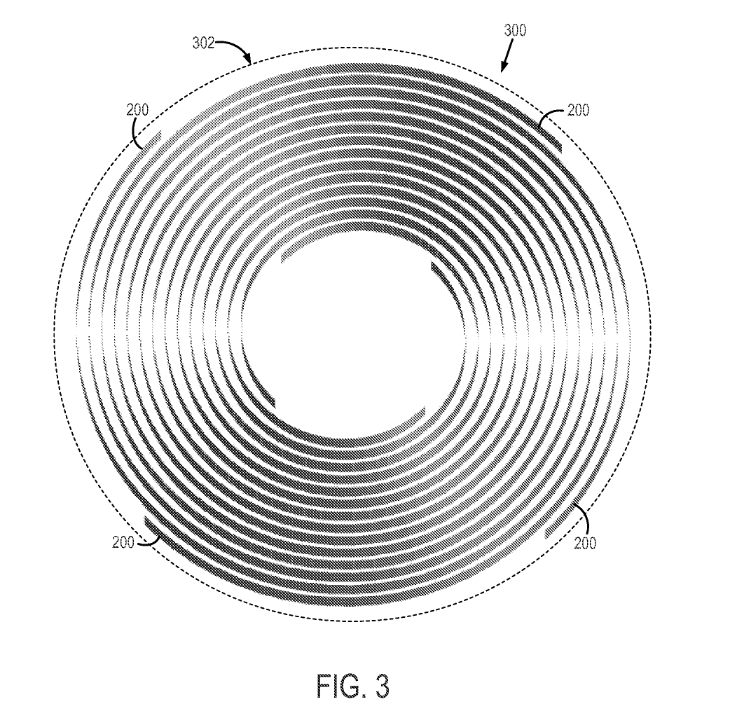

Thus, a structure with no RF currents parallel to conductor edges would be beneficial to reduce proximity effect. A portion of such a structure can be seen in FIG. 4, as tube coil 400. FIG. 4 illustrates a cut-away view of a plurality of overlapping concentric conductor tubes 402, 404. The plurality of conductor tubes 402, 404 can interleave with each other to form layers that overlap in an overlap region 406. In one embodiment, the conductor tubes 402, 404, interleaved together, can be bent into a torus. Where the conductor tubes 402, 404 are formed into a torus structure, the magnetic field in the coil can increase, layer by layer. The magnetic field can be weakest on the innermost layer of the torus, and strongest on the outermost layer.

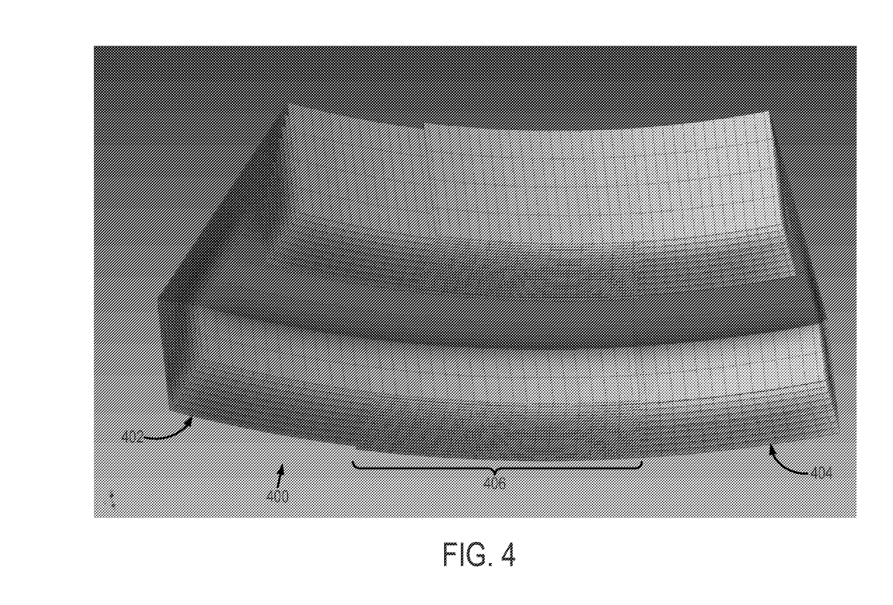

A further embodiment can be seen in FIGS. 5A-5C. FIGS. 5A and 5B present a side view and a top view, respectively, of an example toroidal coil 500. The toroidal coil 500 can include a plurality of interleaved poloidal conductors 502 repeated and formed into a torus. In one example, the poloidal conductors can be constructed using folded-gap loops. An example section of such a configuration is illustrated in FIG. 5C, in which the poloidal conductors 502 include a first set of conductors 502a interleaved with a second set of conductors 502b that overlap in an overlap region 506. In another example, the poloidal conductors 502 can be constructed as a single spiral conductor having a poloidal cross-section that would look similar to the spiral coil shown in FIG. 2A, or a plurality of interleaved spiral conductors having a poloidal cross-section that would look similar to the spiral coils shown in FIG. 3.

In some configurations, such as the one shown in FIG. 5D, a radial cut 504 can be made around the outer conductors to prevent currents from flowing around the poloidal spiral. While radial cut 504 can prevent currents from flowing around the poloidal spiral, the radial cut 504 can form conductor edges along the direction of current flow, which can increase proximity effect, as discussed above. However, the radial cut 504 can be placed where the RF magnetic field is at a minimum. Placing the radial cut 504 at a location with the lowest RF magnetic field strength can serve to mitigate adverse proximity effects, as discussed above.

A further envisioned structure is a coaxial cable, where the inner conductor includes interleaved, partially overlapping conductor/dielectric spirals. The spirals can be in the azimuthal direction. This structure can be similar to the toroidal coil 500. In the coaxial cable application the toroidal coil 500 could be straightened out in the axial direction. The coaxial cable construction can function without the radial cut 504 where the cable is orientated in a straight, linear orientation. If the coaxial cable were to be bent, a radial cut can mitigate resulting proximity effects, particularly if the coaxial cable is bent sharply. The structure for the overlapping conductor/dielectric spiral can be constructed by partially overlapping sheets of conductor/dielectric and rolling the overlapping sheets to form the conductor/dielectric spiral.

The above structures can require the use of conductor/dielectric sheets for construction. For the above structures to operate efficiently, the dielectric materials used preferably have low loss tangents at the desired operating frequency. Loss tangent is the ratio of the imaginary portion of the dielectric constant to the real portion of the dielectric constant. The preference for low loss tangent can limit the range of known dielectrics that can be used. Preferred dielectric materials can include: PTFE, polyethylene, polypropylene, polystyrene, paraffin wax, silicon dioxide, glass, and sapphire, as well as materials such as Rogers RT/Duroid® 5880 or other nonconducting materials with minimal RF losses. Alternatively, materials with large dielectric constants can also be used.

Additionally, the conductors can preferably be coupled to the dielectric material for proper operation as well as for integrity of the structure. Generally, adhesives can be used to couple conductors to dielectric material. However, because the adhesive used to adhere the conductor to the dielectric material will also have dielectric properties, the adhesives should be selected as those having a low loss tangent. In one example, an adhesive such as Q-dope, or polystyrene glue can be used. Adhesives that can have high loss tangents can be oil-based gilding size and acrylic based adhesives. Alternatively, some adhesives may be highly conductive. In this case, the adhesive should be factored in to any determination of conductor thickness as the adhesive will act as a conductor and will contribute to the overall conductor thickness.

The adhesives can sometimes dry before the conductor can be adhered to the dielectric material. This issue can be addressed by applying the adhesive thickly to the dielectric material and then using pressure to compress the conductor and the dielectric material together. This can cause the adhesive to flow to the edges and can straighten the conductor. This method is effective where the conductor is a thin foil conductor. Further, the amount of compression used can control the resulting thickness of the adhesive. Alternatively, an adhesive, such as polystyrene glue can be mixed with a lower vapor pressure solvent such as ethylbenzene or propylbenzene. This can thin the adhesive, allowing it to be applied thinly. Further, the solvent can evaporate slowly enough for the conductor to be applied. Where the resulting conductor/dielectric material may need to be bent, adhering the conductor to thin dielectric sheets (˜50 μm) can prevent buckling of the conductor when bent. This thin conductor/dielectric material can then be cut cleanly into strips using a cutting device.

Due to the issues of using adhesives, other possible methods of manufacture can be used. In one example, electrodeposition of a conductor, such as copper, onto PTFE can be used. A further example would be to use physical vapor deposition (PVD) to deposit a conductor, such as copper, onto PTFE.

The above structures can be used to form electromagnetic coils with a variety of applications. Further, the above structures can overcome Q-value limits due to skin depth and proximity effect, even at high operating frequencies such as those required for high/ultra-high magnetic field strengths (e.g., 3 T, 7 T and 9.4 T).

The described benefits of the above structures are particularly useful in the field of medical imaging, and particularly MRI imaging. For example, high field MRI coils are optimally loaded when coil losses equal sample losses. By increasing unloaded Q-values, signal-to-noise ratios can be increased, which can in turn reduce required scan times. Additionally, eddy currents caused by the changing gradient magnetic fields can generate artifacts in MRI images when strong gradient pulses are switched rapidly, leading to MRI image distortion. Reducing conductor thickness to less than a skin depth can reduce eddy currents, particularly at faster scan rates (e.g., 500 MHz), and therefore increase image clarity by eliminating those image distortions caused by these eddy currents.

Additionally, the above disclosed coils can be constructed for use with lower frequency applications as well. At lower frequencies the conductors can be thicker due to the lower frequencies required. These thicker conductors can be constructed to have a strong enough structure to be self-supporting. This self-supporting structure can in some cases be strong enough to eliminate the need for a dielectric material. Where the self-supporting structure is strong enough to not need a dielectric material, air, or a vacuum, can be used as a dielectric in the overlap areas.

These improvements are highly advantageous, as the next generation of clinical MRI scanners will need to operate at higher frequencies due to the larger and stronger magnets used in the systems. Accordingly, the coils will need to be smaller, which can make them susceptible to artifacts and sample losses. The above described high-Q value distributed surface coils composed using the described metamaterials can solve these issues. Further, new coils based on the above technology can be expected to be superior to those already in use. For example, high Q-value MRI coils will improve imaging sensitivity and image quality, and reduce scanning time.

In addition to MRI systems, it is anticipated that the above technology could improve technology in other fields as well. For example, fMRI applications could benefit from the improved coil materials and structures discussed above. Additionally, Nuclear Magnetic Resonance (NMR) coils could also benefit from the reduced resistance and associated heating of coils based on the above technology, eliminating the need to cool current coils to extremely low temperatures in order to reduce ohmic losses. Spectrometers and/or amplifiers could also benefit, as higher Q-value coils can produce higher signal-to-noise ratios. Higher Q-values can also mean decreased power loss, improved efficiency and lower ohmic heating for high power applications. In another example, high-Q resonators can be used for constructing narrow-band, low loss filters used in communication and radar systems.

Additionally, the above technology could also be used in transmission line design. There is a close relationship between transmission lines and resonant structure. Transmission lines can be made into a resonant structure by varying the length and type of termination. In one example, reactance can be used as a termination of a transmission line if an appropriate adjustment is made for the length at a particular frequency of operation. Using the above technology, transmission lines based on multiple thin conductors of thickness less than a skin depth would create much more compact power transmission lines.

Examples of various coil designs are now provided and described.

### Example #1: Folded Gap Loop with 10 Sets of Overlapping Conductors

An example of a meta-metallic structure similar to the one illustrated in FIG. 1A can be constructed to include 10 sets of 10 foil layers that form a loop. Each foil set wraps 51 degrees and overlaps with the next set on each end for 15 degrees. The capacitance of the overlapping regions was designed to resonate with the inductance of the loop at a frequency of 400 MHz. The structure was simulated using the finite element computer program Ansys High Frequency Structure Simulator (HFSS) (Canonsburg, Pa.).

The current in each layer is directed primarily around the loop. The current is maximum in the non-overlapping regions, decreases in the overlapping regions and goes to zero on the ends of the foils. The current magnitude in a foil layer is substantially proportional to the area of overlap with adjacent foils. For illustration purposes, the foil material was chosen to be stainless steel with a conductivity of 1.1 MS/m, which has a skin depth of 24 μm at 400 MHz. The foil thickness is 11 μm.

The magnetic field is largest on the inside of the loop and is weaker (and oppositely directed) on the outside. The magnetic field strength also steps across the foil layers. The magnetic field zero is near the third outermost foil layer.

The electric field is significantly stronger in the overlapping foil regions than in the non-overlapping foil regions. The inner loop diameter is 10 mm, the outer loop diameter is 11.4 mm, and the distance between overlapping foils is 25 μm. A conducting shield was placed at a diameter of 20 mm. The Q-value of the structure is 587. This can be compared to a simulated Q-value of 242 for a 1-loop-1-gap loop gap resonator (LGR) of the same inner and outer diameters in the same shield and with a lossless capacitive gap.

If the foil thickness is on the order of a skin depth or less, the typical metallic boundary condition relating the current per unit width, J, to the surface normal vector, \hat{n}, and magnetic field, H, just outside the conducting surface, J=\hat{n}×H, no longer applies. This boundary condition is the default for high frequency finite element computer programs including Ansys HFSS. If this boundary condition is used for a foil structure configured as shown in FIG. 1A, a Q-value of 3.4 results. This is because RF current flows in opposite directions on the inner and outer sides of each foil and is much larger in magnitude than the current in each foil.

In order to obtain proper numerical solutions, it is necessary to solve for the fields inside the metal foil and use a mesh with elements of size smaller than a skin depth. Small mesh can make the simulations computationally intense and require significant quantities of random access memory (RAM). In addition, for the foil and LGR structures considered here, the ends of the structures were not simulated; a perfect magnetic boundary was used. As such, the resonance frequency and Q-value are independent of axial length. Effects of the ends are discussed below.

For the folded-gap loop with no end effects, the inductance can be estimated from Eqns. (18) and (19). The Q-value is enhanced due to the multiple current paths of thickness, t, and can be estimated from Eqn. (1) using a resistance computed as,

$$R = \frac{π ( {r}_{i} + {r}_{o} )}{σ lNt} ; \qquad ( 23 )$$

where N is the number of foil layers in the non-overlapping region. Because this resistance does not account for the eddy current dissipation, it can result in an overestimate of the Q-value. The capacitance can be expressed as,

$$C = \frac{{C}_{fov}}{{C}_{ov}} ; \qquad ( 24 )$$

where Nₒᵥ is the number of azimuthal overlapping regions and,

$${C}_{fov} = \frac{{ɛ}_{0} {ɛ}_{r} A}{d} . \qquad ( 25 )$$

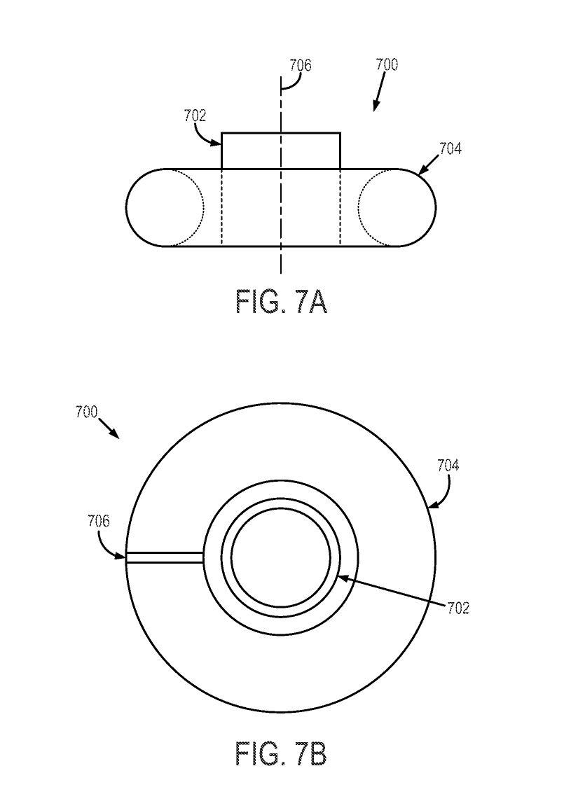

The net area of an overlapping region, A, can be approximated as,

$$A = \frac{( 2 N - 1 ) l {θ}_{ov} ( {r}_{i} + {r}_{o} )}{2} ; \qquad ( 26 )$$

where θₒᵥ is the conductor overlapping angle in radians. FIG. 8 depicts Q-values for various conductor thicknesses for this coil structure, both with 10 foils and with 20 foils.

### Example #2: Folded Gap Loop with 2 Sets of Overlapping Conductors

An example of a meta-metallic structure similar to the one illustrated in FIG. 1C can be constructed to include two sets of 10 foil layers. The structure has an inner radius of 5 mm, an outer radius of 10.8 mm, a spacing between adjacent foil layers of 0.30 mm and an overlap distance of 1.2 mm. By constructing the overlapping foil region with a constant distance instead of angle, the capacitance is constant, which produces more uniform currents across the conductor layers.

A conducting boundary was placed at a radius of 28 mm. The structure resonates at 393 MHz and, for a foil thickness of 1.6 μm, has a Q-value of 5,514. This can be compared to a Q-value of 1,407 for an LGR of the same inner and outer radius and the same metal. The resulting Q-enhancement ratio is 3.9. The eddy current dissipation lowers the Q-enhancement, as expected. The inductance of this folded-gap loop is approximately 2.5 times higher than the inductance of the LGR and this factor has the opposite effect, raising the Q-ratio.

### Example #3: Self-Resonant Spiral

An example of a meta-metallic structure similar to the one illustrated in FIG. 2A can be constructed to include a single spiral coil with an inner radius of 3 mm, an outer radius of 8 mm, 4 turns, and a foil thickness of 2.2 μm. A conducting boundary was placed at a radius of 20 mm. The resonance frequency of this structure is 407 MHz with a Q-value of 2,169. This compares to a Q-value of 809 for an LGR of the same inner and outer radius.

Eddy current dissipation is expected to lower the Q-enhancement; however, the example spiral coil has approximately 1.8 times the inductance of the LGR and this factor raises the Q-enhancement ratio. The nearly sinusoidal (nonuniform) current distribution with foil length in the spiral does not have much effect in lowering the Q-enhancement. For the different structure types that have been simulated, it was found that close attention to balancing the currents by equal capacitance does not significantly impact the Q-value.

An example of a meta-metallic structure similar to the one illustrated in FIG. 3 can be constructed by increasing the number of foil layers. The addition of the duplicate foils has a small effect on the resonance frequency relative to the single foil resonance frequency. The structure shown in FIG. 3 has the same inner and outer radii as the single foil spiral, however, each foil has 3.5 turns and thickness of 1.39 μm. The resonance frequency is 410 MHz and Q-value of 4,139. The LGR comparison is the same, giving an actual Q-enhancement ratio of 5.1.

For a single-foil self-resonant spiral with no end effects, the inductance, resistance, and Q-value can be estimated using the same equations as the folded-gap loop given above, where rᵢ would instead be the minimum foil radius, rₒ would instead be the maximum foil radius, and N would instead be the number of turns of the spiral. For this structure, N does not need to be an integer. The resonance frequency is given by Eqn. (15), with the total capacitance between adjacent layers given by Eqn. (22). For a coil constructed of multiple interleaved spirals, such as the one shown in FIG. 3, there is surprisingly little interaction between the individual spirals. The result is that nearly the same magnetic field is obtained with individual foil currents reduced by the number of individual foils N_{f}. The equations for inductance, resistance, Q-value and frequency are the same as for the single foil spiral except the resistance given by Eqn. (23) is divided by the number of foils,

$$R = \frac{π ( {r}_{i} + {r}_{o} )}{σ {lNtN}_{f}} . \qquad ( 27 )$$

### Example #4: Axial Coil with End Effects

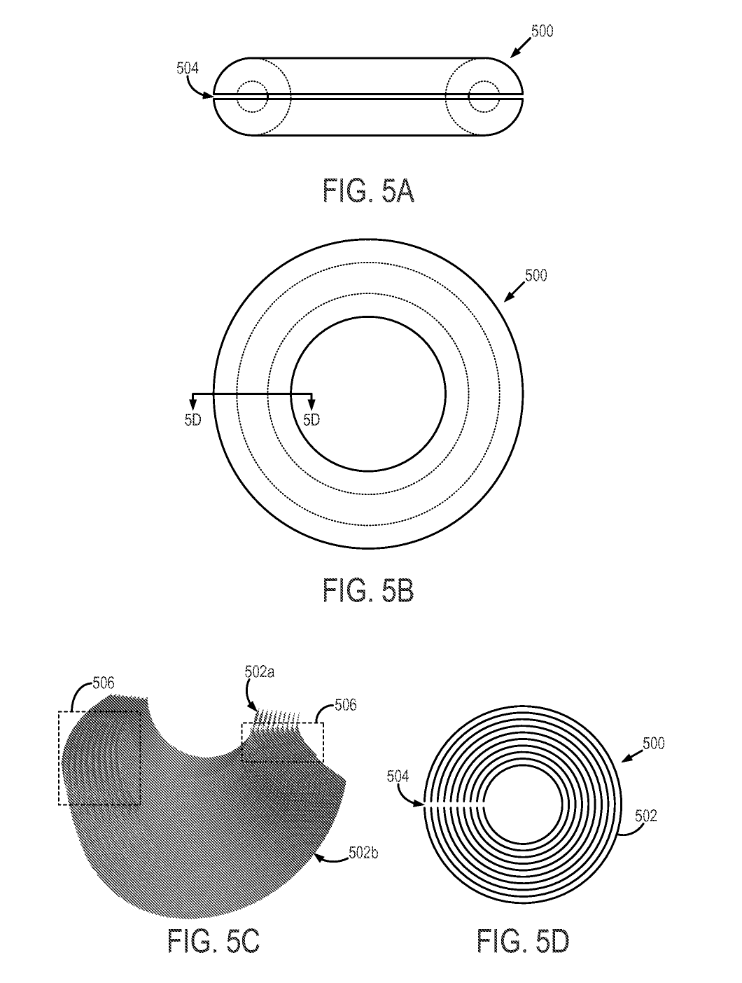

An example of a meta-metallic structure similar to the one illustrated in FIG. 1C, but extended along the axial direction, is illustrated in FIG. 6A. As one example, this axial coil 600 can include two sets of conductors 602, 604 overlapping in overlap regions 606 and extending along the direction of a common axis 610.

In one example, a 1 cm axial length of a folded-gap loop was simulated, for example, by extending the width of each conductor to a length of 1 cm along the axial direction. The finite length of foils were centered in a conducting cylindrical boundary of axial length 40 mm and a radius 25 mm. Intense RF magnetic fields at the axial ends of the foil layers was seen. The intensification is caused by strong RF currents that flow along the foil edges, which in turn cause increased dissipation and a significant decrease in Q-value compared to the structure with no end effects. The structure has an inner radius of 5 mm, an outer radius of 10.9 mm, a spacing between adjacent foil layers of 0.30 mm and an overlap distance of 3 mm. The larger overlap distance was implemented to compensate for the reduced inductance resulting from the finite length. The resonance frequency is 374 MHz.

A maximum Q-value of 731 for this structure was obtained at a thickness of 3.9 μm. This thickness is about 2.4 times the thickness that gives maximum Q-value for the 10-foil structure with no end effects. The Q-value of this structure compares to a Q-value of 1,156 for an LGR of the same inner and outer radius and length, and thus yields a Q-enhancement ratio of 0.63. FIG. 8 depicts Q-values for various conductor thicknesses for this coil structure.

### Example #5: Axial Coil with Dielectric Ends

By treating a folded-gap loop as the central section of a uniform field (“UF”) resonator, it was found that a dielectric region placed on each end of a folded-gap can significantly reduce the strong RF edge currents. The physical principle is that a quarter-wavelength thickness of dielectric converts an electric short at the top of the dielectric to an open impedance, which is presented to the foil edges. The RF open is equivalent to a perfect magnetic boundary condition, the same spatial boundary condition required to keep the RF currents uniform along the axial length of the conductor. An example configuration of such a structure 650 is shown in FIG. 6B, in which a dielectric cap 652 is placed at the axial ends of the axial coil structure 600. Generally, each dielectric cap 652 can be constructed to extend from a bottom surface 654 to a top surface 656 and can be positioned such that is coaxial with the coil structure 600, where the top surface 656 of each cap is distal to the coil structure 600 and the bottom surface 654 of each cap is proximate the conductors in the coil structure 600. In some embodiments, a conductive layer is coupled to the top surface 656 of each dielectric cap 652.

An example of a folded-gap loop composed of four sets of 10 foils was also simulated. The two additional gap regions compared to the axial folded-gap loop illustrated in FIG. 6A were found to be advantageous to couple the foil to the dielectric mode. The foil and dielectric are spaced apart by 0.5 mm and placed inside a conducting shield. The effect of the dielectric is to nearly eliminate the intensification of the RF magnetic field on the foil edges. The structure resonates at 411 MHz and, for a foil thickness of 1.6 μm, has a Q-value of 12,780. The Q-value is maximum at the same foil thickness that produces maximum Q-value for the folded-gap loop with no end effects. The Q-value for this structure is significantly larger than for the folded-gap loop illustrated in FIG. 1C because the dielectric loss tangent was set equal to zero.

The folded-gap loop structure has an inner radius of 5 mm, an outer radius of 10.8 mm, a spacing between adjacent foil layers of 0.30 mm and an overlap distance of 2.4 mm. The dielectric radius is 21.2 mm and length 10 mm. The relative dielectric constant of the dielectric end regions is 760. Dielectrics of larger sizes with relative dielectric constants of 100, 200, and 400 were also been shown to couple to the folded-gap loop of the same size. Similar Q-values were obtained. The relative dielectric constant values of 100-200 are similar to some ceramics. Larger diameter foils and higher resonance frequencies can accommodate dielectrics with even lower relative dielectric constant values.

The folded-gap loop is centered in a conducting cylinder of radius 25 mm and length 31 mm. A 1-loop-4-gap LGR of the same inner and outer radius and length as the folded-gap loop can be coupled to identical dielectric ends. The resulting Q-value is 1,586. The Q-enhancement ratio is 8.1. A larger Q-enhancement is achieved because of the additional inductance of the folded-gap loop compared to the LGR. Using low-loss dielectrics, it is contemplated that this structure can be used to make resonators with Q-values exceeding 10,000. The foil permits a concentration of the RF magnetic field into much smaller volumes and into shapes that are not possible using dielectrics alone.

Self-resonant spiral structures in place of the folded-gap loop were also simulated with dielectric ends with similar results. It was found that a larger gap between the dielectric and the foil (e.g., 1 mm) may be required for a spiral than for a folded-gap loop to prevent capacitive loading of the foil ends by the dielectric. This is due to the larger voltage between the foil ends of the spiral. The loading causes enhanced RF currents on the foil edges. FIG. 8 depicts Q-values for various conductor thicknesses for this coil structure.

### Example #6: Axial Coil with Single Dielectric End

It was found that a dielectric region of about twice the size of a uniform field end section described above, placed on one side of an axial coil, such as a self-resonant spiral or folded-gap loop, can also suppress the strong RF edge currents on both sides of the foil. This result is because axial length of the foil is much smaller than a free space electromagnetic wavelength. When the resonance frequency of combined structure (dielectric and axial coil) is near the resonance frequency of the axial coil alone with perfect magnetic boundaries, the strong RF edge currents on the foil are substantially eliminated and the Q-value is maximized. An example of such a structure 650 is illustrated in FIG. 6C.

As one example that was simulated, a three-turn spiral of inner radius 4.25 mm, outer radius 7.25 mm and axial length 2.5 mm embedded in PTFE was found to have a resonant frequency of 402 MHz with perfect magnetic axial boundary conditions. With a 3 μm foil thickness the Q-value is 2,506. With a rutile dielectric cylinder, relative dielectric constant 100, radius and axial length 53.6 mm placed coaxially to the spiral at a distance 1 mm away from the edge of the foil, the combined structure had a resonance frequency of 409 MHz. The spiral was centered in a conducting boundary of radius 53.6 mm and axial length 111.7 mm. The Q-value of the combined structure was 84,750. The Q-value of the combined structure was higher than the spiral alone because there is a large portion of stored energy in the dielectric. The RF magnetic field strength was about the same in the spiral center as the dielectric center. The RF magnetic field in the spiral and dielectric were in-phase, consistent with the lowest frequency parallel mode described in a dielectric-cavity coupled system. The cylindrical dielectric end cap 650 can be referred to as an “equalization” element for the meta-metallic structure.

### Example #7: Self-Resonant Spiral or Folded-Gap Loop with Equalization Coil

It was found that a resonant coil placed near a meta-metallic coil structure can produce substantially the same effect as the dielectric equalization element described above with respect to FIGS. 6B and 6C. The condition for maximum Q-value is the same. Such a coil can be referred to as a “steering coil” or an “equalization coil” for the meta-metallic structure. The equalization coil is designed to equalize the current flowing in each conductor in a meta-metallic coil structure along the axial dimension. That is, the equalization coil operates to make the current at the edges of each conductor substantially equal to the current at the center of each conductor, thereby resulting in axially uniform current flowing through each conductor. This arrangement prevents the buildup of currents on the edge of the conductors.

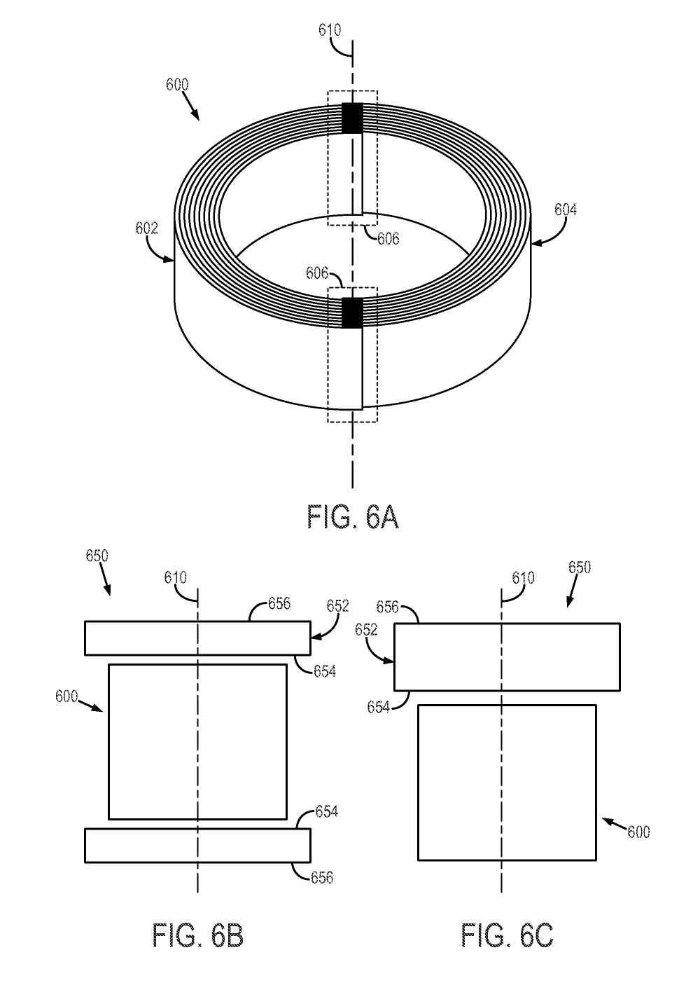

An example of such a structure is illustrated in FIGS. 7A and 7B, in which the meta-metallic coil structure 700 includes a meta-metallic coil structure 702 and an equalization coil 704, which can be another meta-metallic coil structure or not. The coil structure 702 can be constructed in accordance with the descriptions provided above. In some embodiments, the equalization coil 704 can also be constructed in accordance with the descriptions provided above. Preferably, the coil 702 and equalization coil 704 are coaxial with a common axis 706. The bottom edges of both coils 702, 704 can be coplanar, as shown in FIG. 7A. The equalization coil 704 can include a capacitor 706 for tuning the equalization coil 704 to the desired resonance frequency of the coil structure 702.

As one example, a meta-metallic coil structure 700 is constructed to include a coil 702 constructed as a three-turn copper spiral coil with an inner radius 4.25 mm, outer radius 7.25 mm, axial length 5 mm, 3 μm foil thickness, and is embedded in PTFE. The coil 702 is coaxial with the equalization coil 704, which is constructed as a self-resonant toroidal coil made of silver with major radius of 17 mm and a minor radius of 5 mm. The bottom edges of both coils 702, 704 are coplanar. The equalization coil 704 has a capacitive gap of thickness 98 μm filled with rutile to make it self-resonant. The capacitive gap thickness was adjusted so that the coupled system 700 resonated near 400 MHz. The Q-value of the coupled system 700 is 2,057 at 396 MHz. Further adjustments would increase the Q-value slightly. The Q-value of the equalization coil 704 alone is 2,633 at 400 MHz. Therefore, most of the losses were due to the equalization coil 704 and not the self-resonant spiral coil 702. If the equalization coil 704 was made lossless, the Q-value of the coupled system 700 would be 4,640. This Q-value is higher than the spiral alone with perfect magnetic boundaries due to the additional stored energy near the equalization coil.

This coupled system 700 can be used as a practical surface coil for MRI. Because the RF magnetic fields of the spiral 702 and the equalization coil 704 are in phase, the depth sensitivity below the self-resonant spiral coil 702 is enhanced by the equalization coil 704. The Q-value can be tailored to whatever it needs to be to produce dominant loading, which is where the subject to be imaged absorbs at least as much power from the coil as the power losses in the coil itself. A wide variety of different types of equalization elements could be used. The equalization coil could be used as a coupling structure.

### Example #8: Toroidal Loop Coil

Another structure that minimizes foil edge currents is a folded-gap toroidal loop, an example of which is illustrated in FIGS. 5A-5D. The structure has an overall shape of a torus, but the symmetry of the folded gaps is in the poloidal direction instead of the axial direction of the folded-gap loops, as shown in FIG. 5C. Thus, the foils have the shape of concentric rings.

An example of a toroidal loop coil was simulated. This example structure was simulated to have 10 sets of 10 foils with overlapping and non-overlapping regions distributed azimuthally similar to the folded-gap loop coil shown in FIG. 1A. The RF currents are directed primarily around the loop. Outside of the outermost foil, the RF magnetic field distribution is similar to a thick loop of wire carrying an RF current around the loop.

Inside the foils, the RF magnetic field magnitude steps down across the foils similar to that seen for the folded-gap loop. The magnetic field on the inside of the innermost foil is zero. The major radius of the simulated example toroidal loop was 6.78 mm, the minor radius was 1.74 mm, and the spacing between foil layers was 76 μm. The structure was centered in a cylindrical conducting boundary of radius and length 14 mm.

Results of a numerical study of the dependence of the Q-value of the structure with conductor thickness is shown in FIG. 8. It can be seen that the maximum Q-value is obtained at a foil thickness of about 1.4 μm, nearly the same as for the folded-gap loop with no end effects. The maximum Q-value is 1,953. This Q-value can be compared to that of a thick conducting loop of copper of the same major and minor radii with a gap and centered in a conducting boundary of the same size. With the gap capacitance adjusted to produce a resonance frequency of 400 MHz, simulations show a resulting Q-value of 1,131. This corresponds to a Q-enhancement factor of 1.7, which is about half of what would be expected based on theory alone.

The reason for this reduced Q-enhancement has to do with the RF current distribution in the foils. Examination of the current distribution in the foils of the structure using Ansys HFSS revealed significant poloidally directed currents caused by the relatively large overlapping regions of the outer gaps compared to the inner gaps. The RF currents flow from these capacitive regions poloidally to the innermost regions of the foils and then back poloidally to the next capacitor. The RF current paths are inefficient compared to those in the thick conducting loop and the Q-value enhancement ratio is decreased. This effect can be reduced by reducing the ratio of the minor radius to the major radius.

An alternative, and simpler, method for constructing a toroidal loop coil is to replace the folded-gap loops with a single poloidally-spiraled N-turn foil. This single foil should then be cut azimuthally in order to break currents that tend to flow from inner foil layers to outer foil layers, as illustrated in FIG. 5D.

For the toroidal loop, the inductance can be approximated as,

$$L = {μ}_{0} {r}_{M} ( ln ( \frac{8 {r}_{M}}{{r}_{m}} ) - 2 ) ; \qquad ( 28 )$$

where r_{M} is the major radius and rₘ is the average minor radius of the torus,

$${r}_{m} = \frac{{r}_{mi} + {r}_{mo}}{2} ; \qquad ( 29 )$$

where rₘᵢ is the inner minor radius of the foil and rₒ is the outer minor radius of the foil. The resonance frequency is given by Eqn. (15) with the capacitance given by Eqns. (24) and (25), but where the overlapping area is now,

A=(2N−1)πθₒᵥr_{M}(rₘᵢ+rₘₒ) (30);

where θₒᵥ is the foil overlapping angle in radians.

### Example #9: Coaxial Cable

As an example, a 5 mm length of coaxial cable was made with the inner conductor replaced by two sets of 10 axially overlapping foils. The outer conductor (inner) radius was chosen to be 28 mm, the inner foil radius 5 mm and outer foil radius 7.4 mm. With each end of the coaxial cable shorted, the capacitance between the foils was designed for a resonance frequency near 400 MHz using the transmission line impedance equation as follows:

$${Z}_{i} + \frac{1}{j ω C} = 0. \qquad ( 31 )$$

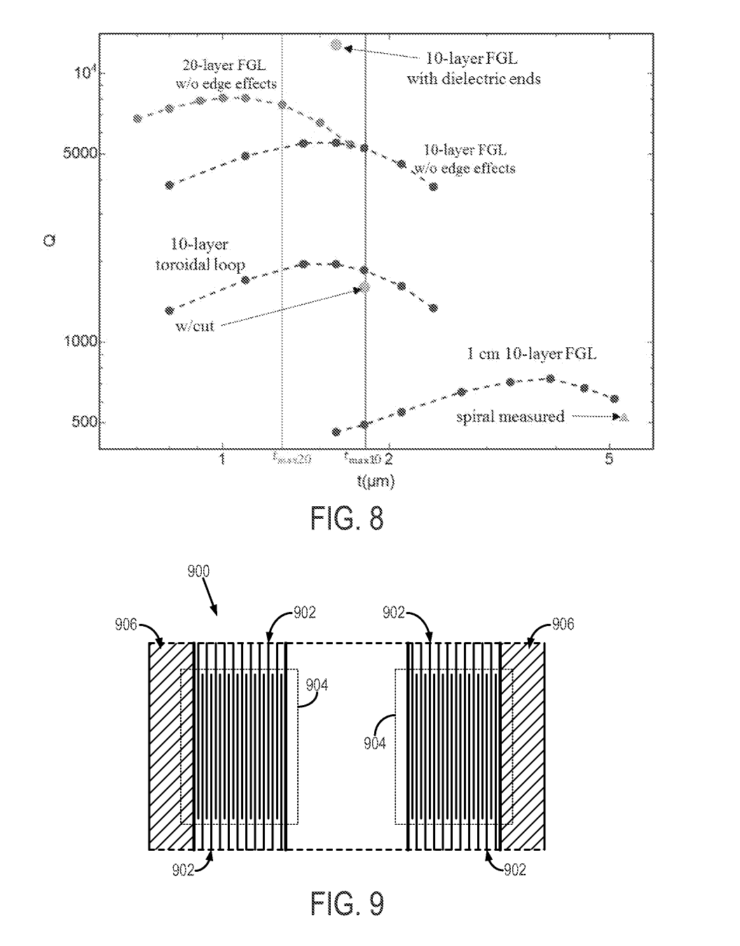

A cut view of the cable showing the foils and the outer shield is shown in FIG. 9. In this example, the coaxial cable 900 includes conductive layers 902 that overlap in an overlap region 904 and are contained within an outer conductive shield 906. With the spacing between adjacent foil layers of 0.13 mm and an axial overlap distance of 0.9 mm the structure is resonant at 396 MHz. At a foil thickness of 1.6 μm, the Q-value of the structure has a maximum value of 19,718. This can be compared to a Q-value of 5,302 for the same coaxial length with the foils replaced by a thick inner conductor with an outer radius the same as the average radius of the foils, 6.3 mm. The corresponding Q enhancement factor is 3.7.

A much longer structure with no shorted ends and many capacitive regions could be used as a coaxial cable transmission line. As such, it would exhibit some dispersion due to the capacitive regions. This property is unlike a coaxial cable with a thick inner conductor, which carries a pure TEM mode, but is similar to standard waveguide. The amount of dispersion can be adjusted through the capacitance.

It will be appreciated by those skilled in the art that the meta-metallic structures described here can also be adapted for use in other devices, including transmission lines and antennas.

The present invention has been described in terms of one or more preferred embodiments, and it should be appreciated that many equivalents, alternatives, variations, and modifications, aside from those expressly stated, are possible and within the scope of the invention.

What is claimed is:

1. A radio frequency coil, comprising:
a first set of layered conductors, each conductor in the first set of layered conductors having a thickness less than three skin depths for a desired resonance frequency;
a second set of layered conductors, each conductor in the second set of layered conductors having a thickness less than three skin depths for the desired resonance frequency;
at least one overlap region where the first set of layered conductors and the second set of layered conductors overlap, thereby defining an overlap surface area;
a plurality of dielectric layers, each dielectric layer being disposed between a conductor in the first set of layered conductors and a conductor in the second set of layered conductors, such that each conductor in the first set of layered conductors is spaced apart from each conductor in the second set of layered conductors in the overlap region by a separation distance;
wherein the overlap surface area and the separation distance define, in part, a capacitance of the radio frequency coil.

2. The radio frequency coil of claim 1, wherein the first set of layered conductors comprises a first plurality of subsets of conductors with each subset of conductors being arranged in generally parallel layers, and the second set of layered conductors comprises a second plurality of subsets of conductors with each subset of conductors being arranged in generally parallel layers.

3. The radio frequency coil of claim 1, wherein each conductor in the first set of layered conductors has a thickness less than one skin depth for the desired resonance frequency and each conductor in the second set of layered conductors has a thickness less than one skin depth for the desired resonance frequency.

4. The radio frequency coil of claim 1, wherein:
the first set of layered conductors and the second set of layered conductors are wrapped around a cylindrical volume having a radius that defines an inner radius of the radio frequency coil and a height that defines an axial length of the radio frequency coil;
each conductor in the first set of layered conductors and the second set of layered conductors extends along an axis of the cylindrical volume from a first end of the cylindrical volume to a second end of the cylindrical volume by the axial length; and
the inner radius and the axial length define, in part, an inductance of the radio frequency coil.

5. The radio frequency coil of claim 4, further comprising a dielectric end cap coaxial with the axis of the cylindrical volume and positioned proximate the first and second set of layered conductors at the first end of the cylindrical volume.

6. The radio frequency coil of claim 5, wherein the dielectric end cap extends along the axis of the cylindrical volume from a bottom surface proximate the first and second set of layered conductors to a top surface distal to the first and second set of layered conductors, the dielectric end cap further comprising a conductive material disposed on the top surface of the dielectric cap.

7. The radio frequency coil of claim 5, further comprising another dielectric end cap coaxial with the axis of the cylindrical volume and positioned proximate the first and second set of layered conductors at the second end of the cylindrical volume.

8. The radio frequency coil of claim 7, wherein:
the dielectric end cap extends along the axis of the cylindrical volume from a bottom surface proximate the first and second set of layered conductors to a top surface distal to the first and second set of layered conductors, the dielectric end cap further comprising a conductive material disposed on the top surface of the dielectric cap; and
the another dielectric end cap extends along the axis of the cylindrical volume from a bottom surface proximate the first and second set of layered conductors to a top surface distal to the first and second set of layered conductors, the another dielectric end cap further comprising a conductive material disposed on the top surface of the another dielectric cap.

9. The radio frequency coil of claim 1, wherein the first set of layered conductors and the second set of layered conductors comprise layers of metallic gilding foil.

10. (canceled)

11. The radio frequency coil of claim 1, further comprising an adhesive coupling one of the plurality of dielectric layers to each of the conductors in the first set of layered conductors and coupling one of the plurality of dielectric layers to each of the conductors in the second set of layered conductors.

12-14. (canceled)

15. The radio frequency coil of claim 1, wherein the capacitance is selected to define, in part, the desired resonance frequency as a resonance frequency for use in at least one of magnetic resonance imaging, nuclear magnetic resonance, or electron paramagnetic resonance.

16. A radio frequency coil assembly comprising:
a radio frequency coil according to claim 1;
a second coil coaxial with and disposed about an outer radius of the radio frequency coil.

17. The radio frequency coil assembly of claim 16, wherein the second coil comprises a radio frequency coil according to claim 1.

18. A self-resonant radio frequency coil, comprising:
a conductor being spiraled about a central axis for a number of turns to form a coil with an inner radius and an outer radius that define, in part, an inductance of the radio frequency coil;
a dielectric material coupled on one side of the conductor;
a conductive adhesive coupling the conductor to the dielectric material, wherein a combined thickness of the conductive adhesive and the conductor is less than three skin depths for the desired resonance frequency;
wherein the number of turns, the inner radius, and the conductor thickness are selected to define, in part, a capacitance of the radio frequency coil; and
wherein the inductance and capacitance of the radio frequency coil are selected to define the desired resonance frequency.

19-23. (canceled)

24. The radio frequency coil of claim 8, wherein the combined thickness is less than one skin depth for the desired resonance frequency.

25. A pancake radio frequency coil, comprising:
a plurality of interleaved dielectric/conductor sheets, each dielectric/conductor sheet spiraled about a common central axis for a number of turns to form a generally round coil of interleaved spirals with an inner radius and an outer radius that define, in part, an inductance of the radio frequency coil, each dielectric/conductor sheet comprising:
a conductor; and
a dielectric material coupled on one side of the conductor; and
a conductive adhesive coupling the conductor to the dielectric material, wherein a combined thickness of the conductive adhesive and the conductor is less than three skin depths for the desired resonance frequency;
wherein the number of turns, the inner radius, and the conductor thickness are selected to define, in part, a capacitance of the radio frequency coil; and
wherein the inductance and capacitance of the radio frequency coil are selected to define the desired resonance frequency.

26-30. (canceled)

31. The radio frequency coil of claim 25, wherein the combined thickness is less than one skin depth for the desired resonance frequency.

32. A high Q-value coil, comprising:
a conductive assembly having at least two overlapping conductive elements that define an overlap area therebetween;
a dielectric material coupled to the conductive assembly and providing a separation distance between the at least two conductive elements in the overlap area; and
wherein a thickness of a conductor in the conductive assembly is selected to minimize countercurrents flowing in the conductive assembly.

33. The coil of claim 32, wherein the conductive assembly comprises a single conductor and the at least two overlapping conductive elements are formed by multiple turns of the single conductor.

34. The coil of claim 32, wherein the conductive assembly comprises a plurality of conductors and the at least two overlapping conductive elements are formed by at least some of the plurality of conductors overlapping each other.

35. The coil of claim 32, further comprising an equalization coil that equalizes currents across an axial width of each conductive element, the equalization coil having an inner diameter and an outer diameter, wherein the inner diameter of the equalization coil is sized to receive the conductive assembly.

36. The coil of claim 35, wherein the equalization coil and the conductive assembly are coaxial.

37. The coil of claim 36, wherein a bottom surface of the equalization coil is coplanar with a bottom surface of the conductive assembly, such that the conductive assembly extends along a common axis from its bottom surface to a top surface that extends a distance beyond a top surface of the equalization coil.

38. The radio frequency coil of claim 11, wherein the adhesive is a conductive adhesive, and a combined thickness of the conductive adhesive and a given conductor to which the conductive adhesive is applied is less than three skin depths for the desired resonance frequency.

39. The radio frequency coil of claim 38, wherein the combined thickness of the conductive adhesive and the given conductor to which the conductive adhesive is applied is less than one skin depth for the desired resonance frequency.
